(19) United States
(12) Patent Application Publication
(10) Pub. No.: US 2026/0043130 A1
(43) Pub. Date: Feb. 12, 2026

(54) ELECTROSTATIC CHUCK FOCUSED PLASMA CLEAN BETWEEN BIAS ELECTRODE AND REMOVABLE ELECTRODE

(71) Applicant: Applied Materials, Inc., Santa Clara, CA (US)

(72) Inventors: Michael R. RICE, Pleasanton, CA (US); James D. CARDUCCI, Sunnyvale, CA (US)

(21) Appl. No.: 18/799,755

(22) Filed: Aug. 9, 2024

(51) Int. Cl. C23C 16/44; C23C 16/458; C23C 16/50; C23C 16/52

(52) U.S. Cl. CPC C23C 16/4405; C23C 16/458; C23C 16/50; C23C 16/52

(57) ABSTRACT

The present disclosure generally provides substrate processing systems and methods thereof. The substrate processing systems include a substrate processing chamber including a transfer port. A substrate support assembly is disposed within the substrate processing chamber. The substrate support assembly having an electrostatic chuck and a substrate support surface. A transport robot is configured to transport a cathode ring in and out of the substrate processing chamber through the transfer port. A controller is configured to cause the substrate processing system to place the cathode ring on the substrate support surface of the substrate support assembly using the transport robot, and power the electrostatic chuck for a cleaning period while the cathode ring is disposed over the substrate support surface

### BACKGROUND

### Field

Embodiments of the present invention generally relate to systems and methods of semiconductor processing and, in particular, to cleaning semiconductor substrate processing chambers.

### Description of the Related Art

Plasma-enhanced chemical vapor deposition (PECVD) is a chemical vapor deposition process used to deposit thin films from a gas state (vapor) to a solid state on a substrate. This process involves chemical reactions that occur after the creation of a plasma of the reacting gases. The plasma is generally created by radio frequency (RF) alternating current (AC) frequency or direct current (DC) discharge between two electrodes, the space between which is filled with the reacting gases.

Cleaning PECVD chambers after a deposition process is crucial to maintain the quality and consistency of the thin films being deposited. However, these methods use the plasma generating resources of the process chambers where they generate a broad plasma throughout the chamber which over clean some areas but insufficiently clean other portions, such as the area at the edge of the electrostatic chuck where thick polymer layers deposit.

Accordingly, there is a need for improved systems and methods for cleaning a substrate processing chamber that does not require as much of the process chamber resources while improving cleaning efficiency.

### SUMMARY

In an embodiment, the present disclosure generally provides substrate processing systems. The substrate processing systems include a substrate processing chamber including a transfer port. A substrate support assembly is disposed within the substrate processing chamber. The substrate support assembly having an electrostatic chuck and a substrate support surface. A transport robot is configured to transport a cathode ring in and out of the substrate processing chamber through the transfer port. A controller is configured to cause the substrate processing system to place the cathode ring on the substrate support surface of the substrate support assembly using the transport robot, and power the electrostatic chuck for a cleaning period while the cathode ring is disposed over the substrate support surface.

In another embodiment, the present disclosure generally provides substrate processing systems. The substrate processing systems include a substrate processing chamber including a transfer port. A substrate support assembly is disposed within the substrate processing chamber. The substrate support assembly having an electrostatic chuck and a substrate support surface. A transport robot is configured to transport a cathode ring in and out of the substrate processing chamber through the transfer port. A controller is configured to cause the substrate processing system to transport a cathode ring from outside of the substrate processing chamber into the substrate processing chamber using the transport robot, place the cathode ring on the substrate support surface of the substrate support assembly using the transport robot, power the electrostatic chuck for a cleaning period while the cathode ring is disposed over the substrate support surface, and remove the cathode ring from the substrate processing chamber after the cleaning period using the transport robot.

In another embodiment, the present disclosure generally provides methods of cleaning a substrate processing chamber. The methods include transporting a cathode ring from outside of a substrate processing chamber into the substrate processing chamber using a transport robot. A cathode ring is placed on a substrate support surface of a substrate support assembly using the transport robot. An electrostatic chuck of the substrate support assembly is powered for a cleaning period while the cathode ring is disposed over the substrate support surface. The cathode ring is removed from the substrate processing chamber after the cleaning period using the transport robot.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and the present disclosure may admit to other equally effective embodiments.

FIG. 1 is a schematic, cross-sectional side view of a processing chamber, according to certain embodiments.

FIG. 2A illustrates a schematic, cross-sectional view of the substrate support having the cathode ring disposed thereon, according to certain embodiments.

FIG. 2B illustrates a close-up, cross-sectional view of a portion of the substrate support having the cathode ring disposed thereon, according to certain embodiments.

FIG. 2C illustrates a schematic, top view of a cathode ring for use in a processing chamber, according to certain embodiments.

FIG. 3 illustrates a block diagram of a method of processing a substrate using a cathode ring, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to systems and methods of semiconductor processing and, in particular, to cleaning semiconductor substrate processing chambers using a removable cathode ring to generate a concentrated plasma near the edge of an electrostatic chuck.

Plasma-enhanced chemical vapor deposition (PECVD) is a chemical vapor deposition process used to deposit thin films from a gas state (vapor) to a solid state on a substrate. This process involves chemical reactions that occur after the creation of a plasma of the reacting gases. The plasma is generally created by radio frequency (RF) alternating current (AC) frequency or direct current (DC) discharge between two electrodes, the space between which is filled with the reacting gases.

Cleaning PECVD chambers after a deposition process is crucial to maintain the quality and consistency of the thin films being deposited. The chamber may be cleaned by an oxygen gas reaction process where the chamber coated with a thin film is mainly cleaned using a reaction with oxygen gas. This process involves introducing oxygen into the chamber, which reacts with the deposited material to form volatile compounds that can be easily removed.

The chamber may be cleaned using a plasma, such as a nitrogen trifluoride (NF3) Plasma. The deposition of multiple layers increases the film thickness on the PECVD chamber wall, which can extend the time required for chamber cleaning. A nitrogen trifluoride (NF3) remote plasma system is often used for this purpose. The chamber may also be physically cleaned where the chamber is vacuumed and the o-ring is wiped down. However, these methods use the process chamber's plasma sources where they generate a broad plasma throughout the chamber which over clean some areas but insufficiently clean other portions, such as the area at the edge of the electrostatic chuck (ESC) where thick polymer layers deposit.

The present disclosure provides systems and methods to generate a high density and low energy plasma locally to where thick polymer deposits on the edge of an ESC using a cathode ring. The plasma generated using the cathode ring will be a capacitively coupled plasma at higher pressures in a narrow gap allowing the plasma to focus on this high deposition area.

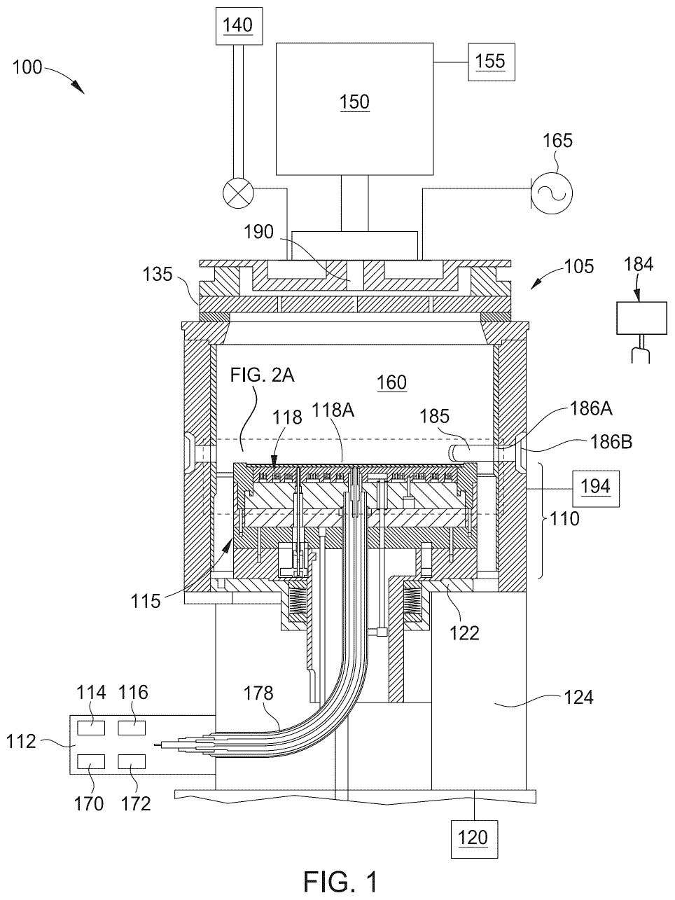

FIG. 1 is a schematic side cross sectional view of an illustrative processing chamber 100 suitable for conducting a deposition process. In one embodiment, which can be combined with other embodiments described herein, the processing chamber 100 may be configured to deposit advanced patterning films onto a substrate, such as hardmask films, for example amorphous carbon hardmask films.

The processing chamber 100 includes a lid assembly 105, a substrate support 115, and a variable pressure system 120. In the embodiment shown, which can be combined with other embodiments described herein, the lid assembly 105 includes a showerhead 135.

The lid assembly 105 is coupled to a first processing gas source 140. The first processing gas source 140 contains precursor gases for forming films on a substrate supported on the substrate support 115. As an example, the first processing gas source 140 includes precursor gases such as carbon containing gases, hydrogen containing gases, helium, among others. In a specific example, the carbon containing gas includes acetylene (C₂H₂).

The lid assembly 105 is also coupled to an optional remote plasma source 150. The remote plasma source 150 is coupled to a cleaning gas source 155 for providing cleaning gases to the processing volume 160 formed between the lid assembly 105 and the substrate. In one example, cleaning gases are provided through a central conduit 190 formed axially through the lid assembly 105. In another example, cleaning gases are provided through the same channels which direct precursor gases. Example cleaning gases include oxygen-containing gases such as oxygen and/or ozone, as well fluorine containing gases such as NF₃, or combinations thereof.

In addition to or as an alternative to the remote plasma source 150, the lid assembly 105 is also coupled to a first or upper radio frequency (RF) power source 165. The first RF power source 165 facilitates maintenance or generation of plasma, such as a plasma generated from a cleaning gas. In one example, the remote plasma source 150 is omitted, and the cleaning gas is ionized into a plasma in situ via the first RF power source 165. The substrate support 115 is coupled to a second or lower RF power source 170. The first RF power source 165 may be a high frequency RF power source (for example, about 13.56 MHz to about 120 MHz) and the second RF power source 170 may be a low frequency RF power source (for example, about 2 MHz to about 13.56 MHz). It is to be noted that other frequencies are also contemplated. In some implementations, the second RF power source 170 is a mixed frequency RF power source, providing both high frequency and low frequency power. Utilization of a dual frequency RF power source, particularly for the second RF power source 170, improves film deposition. In one example, utilizing a second RF power source 170 provides dual frequency powers. A first frequency of about 2 MHz to about 13.56 MHz improves implantation of species into the deposited film, while a second frequency of about 13.56 MHz to about 120 MHz increases ionization and deposition rate of the film.

One or both of the first RF power source 165 and the second RF power source 170 are utilized in creating or maintaining a plasma in the processing volume 160. For example, the second RF power source 170 may be utilized during a deposition process and the first RF power source 165 may be utilized during a cleaning process (alone or in conjunction with the remote plasma source 150). In some deposition processes, the first RF power source 165 is used in conjunction with the second RF power source 170. During a deposition or etch process, one or both of the first RF power source 165 and the second RF power source 170 provide a power of about 100 Watts (W) to about 20,000 W in the processing volume 160 to facilitation ionization of a precursor gas. In one embodiment, which can be combined with other embodiments described herein, at least one of the first RF power source 165 and the second RF power source 170 are pulsed. In another embodiment, which can be combined with other embodiments described herein, the precursor gas includes helium and C₂H₂. In one embodiment, which can be combined with other embodiments described herein, C₂H₂ is provided at a flow rate of about 10 sccm to about 1,000 sccm and He is provided at a flow rate of about 50 sccm to about 10,000 sccm.

The substrate support 115 is coupled to a facilities cable 178 that is flexible which allows vertical movement of the substrate support 115 while maintaining communication with the second RF power source 170 as well as other power and fluid connections.

The processing chamber 100 also includes a substrate transfer port 185. The substrate transfer port 185 is selectively sealed by an interior door 186A and an exterior door 186B. Each of the doors 186A and 186B are coupled to actuators (not shown). The doors 186A and 186B facilitate vacuum sealing of the processing volume 160. The doors 186A and 186B also provide symmetrical RF application and/or plasma symmetry within the processing volume 160. In one example, at least the door 186A is formed of a material that facilitates conductance of RF power, such as stainless steel, aluminum, or alloys thereof. A transfer robot 184 is configured to transport a substrate into and out of the processing chamber 100 using the substrate transfer port 185. A controller 194 coupled to the processing chamber 100 is configured to control aspects of the processing chamber 100 during processing.

The cathode assembly 110 also includes a facilities interface 112. The facilities interface 112 provides connections for RF power as well as other electrical and fluid connections. The facilities interface 112 is coupled to the substrate support 115 via the facilities cable 178. Other connections include a power source 114, a coolant source 116 and a gas supply 172.

The power source 114 is utilized to power an electrostatic chuck 118 having a substrate support surface 118A and that is part of the substrate support 115. The power source 114 may be a DC power source or an RF power source that is coupled to a bias electrode (not shown) in the electrostatic chuck 118. De-chucking is facilitated by a controller (not shown) that drains the electrostatic chuck 118. In addition, the facilities cable 178 is coupled to the power source 170, optionally through a matching network, to facilitate operations within the processing chamber 100. In one example, the facilities cable 178 facilitates transfer of RF power during PECVD process.

The coolant source 116 contains a coolant that chills the substrate support 115. For example, a coolant that from the coolant source 116 is flowed to the substrate support 115 to maintain a temperature of the electrostatic chuck 118 (and/or a substrate positioned thereon) at about 25 degrees Celsius or less. The electrostatic chuck 118 (and/or a substrate positioned thereon) may be maintained at a cryogenic temperature not greater than about −40 degrees Celsius. The cryogenic temperature enables ions to bombard the upward facing surfaces of the substrate and/or materials disposed on the substrate with decreased spontaneous deposition or etching to result in improved uniformity and properties of the deposited or etched film. The coolant includes a fluid, for example, a perfluoropolyether fluorinated fluid to maintain the cryogenic temperature.

The gas supply 172 provides a fluid to a space below the electrostatic chuck 118 in order to prevent condensation. The fluid may be clean dry air, nitrogen (N₂), helium (He), or other suitable gas. The fluid supplied to the space below the electrostatic chuck reduces condensation onto the electrostatic, including lower surfaces thereof.

Also shown in FIG. 1 is a support structure 122. While only one is shown, the support structure 122 has three vacuum channels 124 formed therein. The vacuum channels 124 are coupled to the variable pressure system 120. The vacuum channels 124 facilitate symmetrical pumping from the processing volume 160.

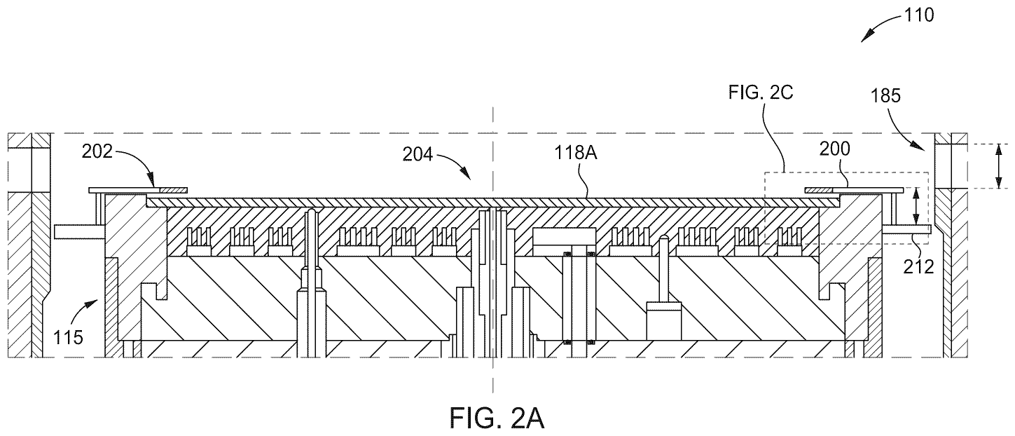

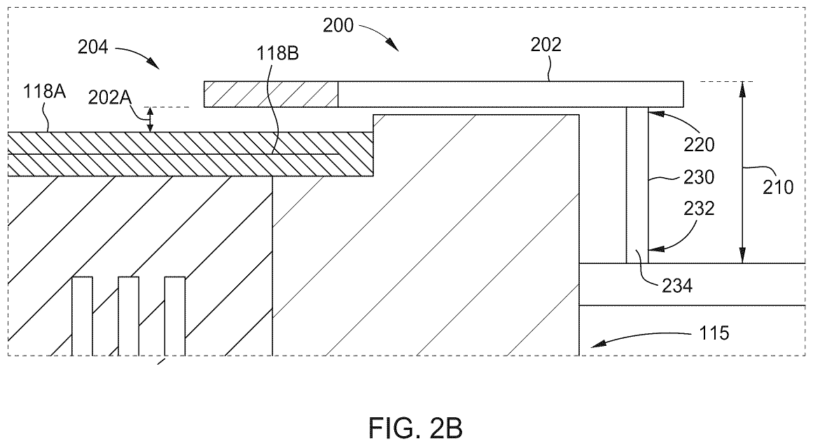

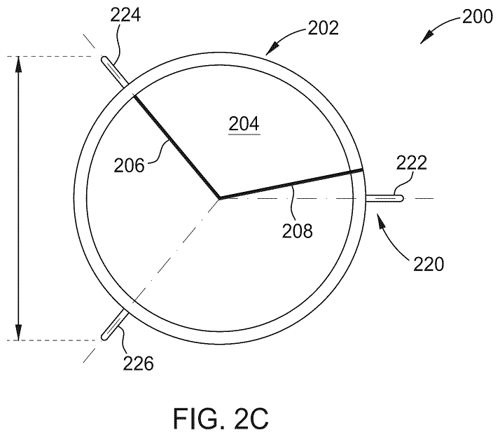

FIG. 2A illustrates a schematic, cross-sectional view of the substrate support 115 having a cathode ring 200 disposed thereon, according to certain embodiments. FIG. 2B illustrates a close-up, cross-sectional view of a portion of the substrate support 115 having the cathode ring 200 disposed thereon, according to certain embodiments.

The cathode ring 200 includes a ring body 202, a central aperture 204, and one or more support legs 220. The cathode ring 200 is removable, e.g., using the transfer robot 184, and, during use, is disposed over an outer perimeter of the substrate support surface 118A. As shown in FIG. 2B, the cathode ring 200 has a ring height 210 that allows the ring body 202 to extend over the substrate support surface 118A at a ring gap distance 202A. The ring gap distance 202A may be about 1 mm to about 20 mm. The ring gap distance 202A allows for the cathode ring 200 and the electrostatic chuck 118 to generate a high pressure, low energy plasma that cleans the substrate support surface 118A between the bias electrode 118B of the electrostatic chuck 118 and the cathode ring 200, which coincides with the outer edge of the substrate support assembly electrostatic chuck 118.

The one or more support legs 220 electrically couple the cathode ring 200 to an electrical ground 212 of the substrate processing chamber. This may be achieved through direct contact of the one or more support legs 220, e.g., where the one or more support legs include an electrically conductive leg body 230, with the electrical ground 212. Alternatively, each of the one or more support legs 220 may include a dielectric tip 234 on a bottom portion 232 of a leg body 230 configured to electrically couple each of the one or more support legs 220 to an electrical ground 212 of the substrate processing chamber. When the cathode ring 200 is disposed over the electrostatic chuck 118 and an electrode of the electrostatic chuck 118, particularly the bias electrode 118B, is powered on, a plasma is generated over an outer perimeter of the substrate support surface 118A when the electrostatic chuck 118 is powered beneath the cathode ring 200.

FIG. 2C illustrates a schematic, top view of the cathode ring 200 for use in a processing chamber, according to certain embodiments. The central aperture 204 of the cathode ring 200 includes an aperture radius 206 that is less than the ring radius 208 but also large enough to expose a majority of the substrate support surface underneath the cathode ring 200. This allows the cathode ring 200 to focus the plasma it generates with the electrostatic chuck 118 to be focused on the outer perimeter or outer edge of the substrate support surface where thick polymer deposits reside while not also over-cleaning the central portion of the substrate support surface.

As shown in FIG. 2C, the one or more support legs 220 include a first leg 222, a second leg 224, and a third leg 226 spaced radially equidistant from each other to provide sufficient support for the cathode ring 200.

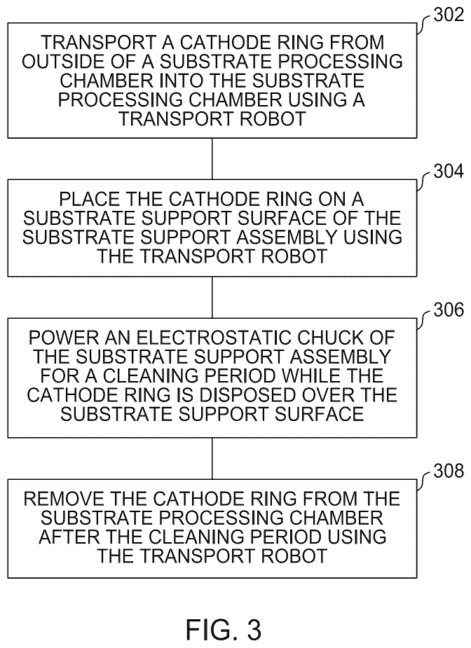

FIG. 3 illustrates a block diagram of a method 300 of processing a substrate using a cathode ring, according to certain embodiments. The method 300 may be executed by a controller, e.g., the controller 194, of a processing chamber, e.g., the processing chamber 100.

The method 300 begins with operation 302 by transporting a cathode ring from outside of a substrate processing chamber into the substrate processing chamber using a transport robot. Transporting the cathode ring from outside of the substrate processing chamber may include passing the cathode ring through a transfer port of the processing chamber using the transport robot 184.

In operation 304, the cathode ring is placed on a substrate support surface of the substrate support assembly using the transport robot 184. Once placed, the cathode ring may be disposed a distance of about 1 mm to 20 mm above the substrate support surface. In particular, placing the cathode ring on the substrate support surface includes electrically coupling the cathode ring to an electrical ground 212 of the substrate processing chamber. This may be achieved using the support legs of the cathode ring which may be directly coupled or capacitively coupled to the electrical ground 212. Capacitively coupling the cathode ring to the electrical ground 212 may use a dielectric tip of one or more support legs of the cathode ring.

In operation 306, an electrostatic chuck of the substrate support assembly is powered for a cleaning period while the cathode ring is disposed over the substrate support surface. After powering the electrostatic chuck, a plasma is generated between the electrostatic chuck and the cathode ring which is configured to clean an outer perimeter of the substrate support surface. Although the plasma generated by the electrostatic chuck and the cathode ring is used to clean or etch the outer perimeter in method 300, it is within the scope of this disclosure that the plasma generated may be used to deposit material onto a substrate, e.g., during PECVD, to provide further deposition uniformity on the outer edges of the substrate.

In operation 308, the cathode ring is removed from the substrate processing chamber after the cleaning period using the transport robot.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another—even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

1. A substrate processing system, comprising:
a substrate processing chamber comprising:
a transfer port; and
a substrate support assembly disposed within the substrate processing chamber and having an electrostatic chuck and a substrate support surface;
a transport robot configured to transport a cathode ring in and out of the substrate processing chamber through the transfer port; and
a controller configured to cause the substrate processing system to:
place the cathode ring on the substrate support surface of the substrate support assembly using the transport robot; and
power the electrostatic chuck for a cleaning period while the cathode ring is disposed over the substrate support surface.

2. The substrate processing system of claim 1, wherein the cathode ring comprises a ring body, a central aperture, and one or more support legs.

3. The substrate processing system of claim 1, wherein the cathode ring is disposed over an outer perimeter of the substrate support surface.

4. The substrate processing system of claim 2, wherein the one or more support legs electrically couple the cathode ring to an electrical ground of the substrate processing chamber.

5. The substrate processing system of claim 2, wherein each of the one or more support legs comprise a dielectric tip on a bottom portion of a leg body configured to electrically couple each of the one or more support legs to an electrical ground of the substrate processing chamber.

6. The substrate processing system of claim 1, wherein the cathode ring and the electrostatic chuck generate a plasma over an outer perimeter of the substrate support surface when the electrostatic chuck is powered.

7. The substrate processing system of claim 1, wherein the cathode ring is disposed above the substrate support surface by a distance of about 1 mm to about 20 mm.

8. A substrate processing system, comprising:
a substrate processing chamber comprising:
a transfer port; and
a substrate support assembly disposed within the substrate processing chamber and having an electrostatic chuck and a substrate support surface;
a transport robot configured to transport a cathode ring in and out of the substrate processing chamber through the transfer port; and
a controller configured to cause the substrate processing system to:
transport a cathode ring from outside of the substrate processing chamber into the substrate processing chamber using the transport robot;
place the cathode ring on the substrate support surface of the substrate support assembly using the transport robot;
power the electrostatic chuck for a cleaning period while the cathode ring is disposed over the substrate support surface; and
remove the cathode ring from the substrate processing chamber after the cleaning period using the transport robot.

9. The substrate processing system of claim 8, wherein the cathode ring comprises a ring body, a central aperture, and one or more support legs.

10. The substrate processing system of claim 8, wherein the cathode ring is disposed over an outer perimeter of the substrate support surface.

11. The substrate processing system of claim 9, wherein the one or more support legs electrically couple the cathode ring to an electrical ground of the substrate processing chamber.

12. The substrate processing system of claim 9, wherein each of the one or more support legs comprise a dielectric tip on a bottom portion of a leg body configured to electrically couple each of the one or more support legs to an electrical ground of the substrate processing chamber.

13. The substrate processing system of claim 8, wherein the cathode ring and the electrostatic chuck generate a plasma over an outer perimeter of the substrate support surface when the electrostatic chuck is powered.

14. The substrate processing system of claim 8, wherein the cathode ring is disposed above the substrate support surface by a distance of about 1 mm to about 20 mm.

15. A method of cleaning a substrate processing chamber, comprising:
transporting a cathode ring from outside of a substrate processing chamber into the substrate processing chamber using a transport robot;
placing the cathode ring on a substrate support surface of a substrate support assembly using the transport robot;
powering an electrostatic chuck of the substrate support assembly for a cleaning period while the cathode ring is disposed over the substrate support surface; and
removing the cathode ring from the substrate processing chamber after the cleaning period using the transport robot.

16. The method of claim 15, wherein transporting the cathode ring into the substrate processing chamber comprises passing the cathode ring through a transfer port of the substrate processing chamber using the transport robot.

17. The method of claim 15, wherein placing the cathode ring on the substrate support surface comprises disposing the cathode ring a distance of about 1 mm to 20 mm above the substrate support surface.

18. The method of claim 15, wherein placing the cathode ring on the substrate support surface comprises electrically coupling the cathode ring to an electrical ground of the substrate processing chamber.

19. The method of claim 15, further comprising:
after powering the electrostatic chuck for the cleaning period while the cathode ring is disposed over the substrate support surface, generating a plasma between the electrostatic chuck and the cathode ring configured to clean an outer perimeter of the substrate support surface.

20. The method of claim 15, wherein electrically coupling the cathode ring to the electrical ground comprises capacitively coupling the cathode ring to the electrical ground using a dielectric tip of one or more support legs of the cathode ring.
